(19) United States
(12) Patent Application Publication
(10) Pub. No.: US 2007/0188995 A1
(43) Pub. Date: Aug. 16, 2007

(54) Flow Diversion Heat Sinks For Temperature Uniformity in Back to Back Multi-processor Configurations

(75) Inventors: John Franz, Houston, TX (US); Shailesh Joshi, Houston, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P., Houston, TX (US)

(21) Appl. No.: 11/673,185

(22) Filed: Feb. 9, 2007

Related U.S. Application Data
(60) Provisional application No. 60/773,421, filed on Feb. 15, 2006.

(51) Int. Cl. H05K 7/20

(52) U.S. Cl. 361/704; 165/80.4

(57) ABSTRACT

A system for maintaining heat sink temperature uniformity in a system with pairs of substantially similar components mounted on a surface in close proximity and substantially aligned with an air flow, where the air flow is divided into a plurality of air flows by dividers radiating upward from the heat sink bases' top surfaces and containing cooling fins on the heat sink on only one side of the divider, where each airflow is diverted past the cooling fins of at least one of the heat sinks without significant pre-heating and through the cooling fins of at least one of the other heat sinks.

### CROSS-REFERENCE TO RELATED APPLICATIONS

This application claims priority to an earlier filed U.S. Provisional Application entitled “BACK TO BACK HEAT SINK TEMPERATURE UNIFORMITY THROUGH FLOW DIVERSION”, filed on 15 Feb. 2006, Ser. No. 60/773,421, which provisional application is hereby incorporated by reference into the present application.

### BACKGROUND OF THE INVENTION

### BACKGROUND OF THE INVENTION

The main components of a typical blade server consist of a plurality of CPUs, memory and hard drives. Today's blade servers are extremely dense and, therefore, pose serious cooling challenges to dissipate the heat from high power density components such as, the CPU. In a typical blade server, air is used as a coolant to carry the heat dissipated from the high power density components. To compound the heat dissipation problem, some CPU architecture requires specific memory and processor spacing. These space constraints necessitate that multiple CPUs be arranged back-to-back, a non-ideal location since the preheated air from the front processor tends to thwart efficient cooling of the rear processor. This in turn results in non-uniform case temperatures. Therefore, to dissipate the heat from the processors efficiently, it is necessary to design and develop novel cooling solutions for the back-to-back CPU configurations.

Previous heat sink designs used to achieve case temperature uniformity include using two different heat sinks for front and rear processor with different fin spacing to reduce the preheat or, using one large heat sink that connects both the processors. However, the aforementioned designs have several drawbacks. Multiple heat sink types is not as cost effective as a single heat sink type. One large heat sink connecting both the processors increases the weight of the system unnecessarily when shipped with only one processor. In addition, there are complexities for servicing as well as design issues related to co-planarity.

Therefore, to achieve uniform case temperatures for the forward and the rear processors the design of the heat sinks should meet the following requirements: (a) reduce or eliminate preheat to achieve same case temperatures for both forward and rear processors, (b) standardize the heat sink design for both forward and rear processor to obtain a cost effective solution, and finally, (c) meet the weight/size/service specifications of the system.

### BRIEF SUMMARY OF THE INVENTION

To address these constraints, the inventors developed a single heat sink with an inclined baffle that connects when one is installed in a position rotated with respect to another thus funneling cooler air past the front CPU to the rear CPU's heat sink, and funneling pre-heated air from the front CPU's heat sink around the rear CPU. This standardized heat sink reduces or eliminates preheat of the rear processor and meets weight targets. The heat sink also allows for a certain variation in co-planarity and with a single design for multiple processors, it achieves a quantity cost savings for each system.

### BRIEF DESCRIPTION OF THE DRAWINGS

FIGS. 1 and 2 are isotropic views of a Flow Diversion Heat Sink in accordance with an exemplary embodiment of the invention.

FIG. 3 is a Top View of two Flow Diversion Heat Sinks in a back-to-back configuration in accordance with an exemplary embodiment of the invention.

FIG. 4 is a Top View of a Flow Diversion Heat Sink in accordance with an exemplary embodiment of the invention.

FIG. 5 is a Front View of a Flow Diversion Heat Sink in accordance with an exemplary embodiment of the invention.

FIG. 6 is a Side View of a Flow Diversion Heat Sink in accordance with an exemplary embodiment of the invention.

FIG. 7 is a Bottom View of a Flow Diversion Heat Sink in accordance with an exemplary embodiment of the invention.

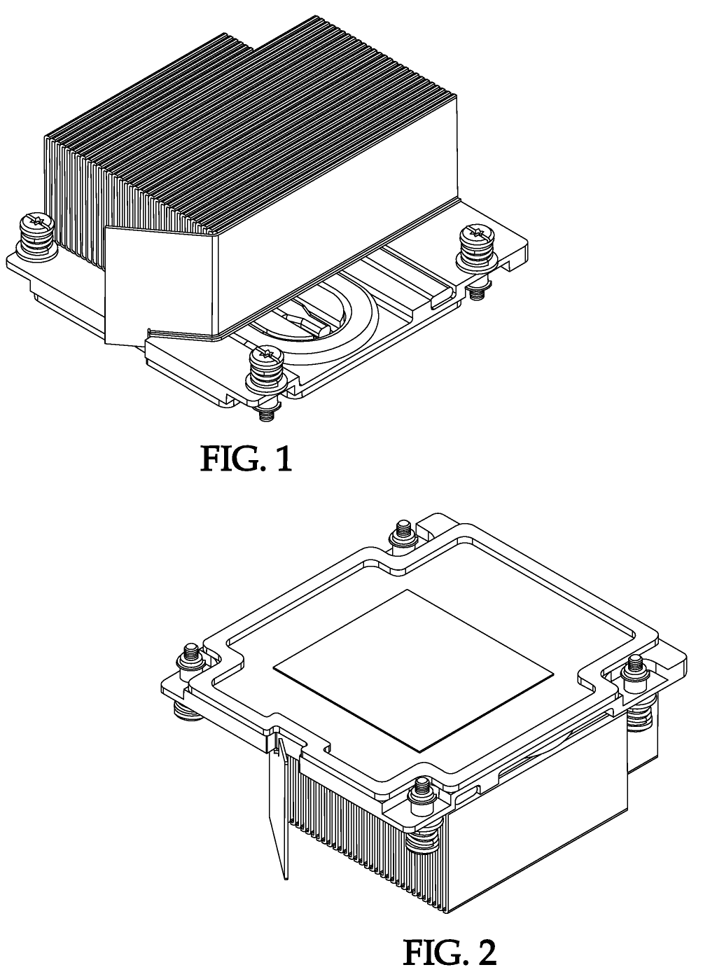

### DETAILED DESCRIPTION OF THE PREFERRED EMBODIMENTS

By dividing the air flowing across the processor region into two paths, each path primarily providing the cooling air flow of a single processor, each processor has the same cooling opportunity. Air passing across the forward processor will not preheat the air thus hampering the cooling of the rear processor. A divider extends from the front of the forward processor's heat sink to the back of the rear processor's heat sink, separating the area above the heat sinks into two separate channels. Air passing across the processors is channeled down one side of the divider or the other. Each heat sink has fins on only one side of the divider such that air flowing through either of the channels passes across the fins of only one of the two processors. As air will flow through the open channel more freely than through the channel, which comprises cooling fins, the channels need not evenly divide the physical space.

Heat pipes imbedded in the heat sink's base plate ensure the entire base plate maintains a similar temperature and reduces or eliminates the unequal cooling of the processor, which may result by the non-uniform distribution of cooling fins. In some embodiment's the mass and/or material of the heat sink's base may adequately distribute the heat of the processor eliminating the need for the heat pipes as a means for evenly distributing the heat. If heat is not distributed correctly, the side of the processor, which is covered by the clear air channel (the absence of cooling fins), may experience an excessive heat build up.

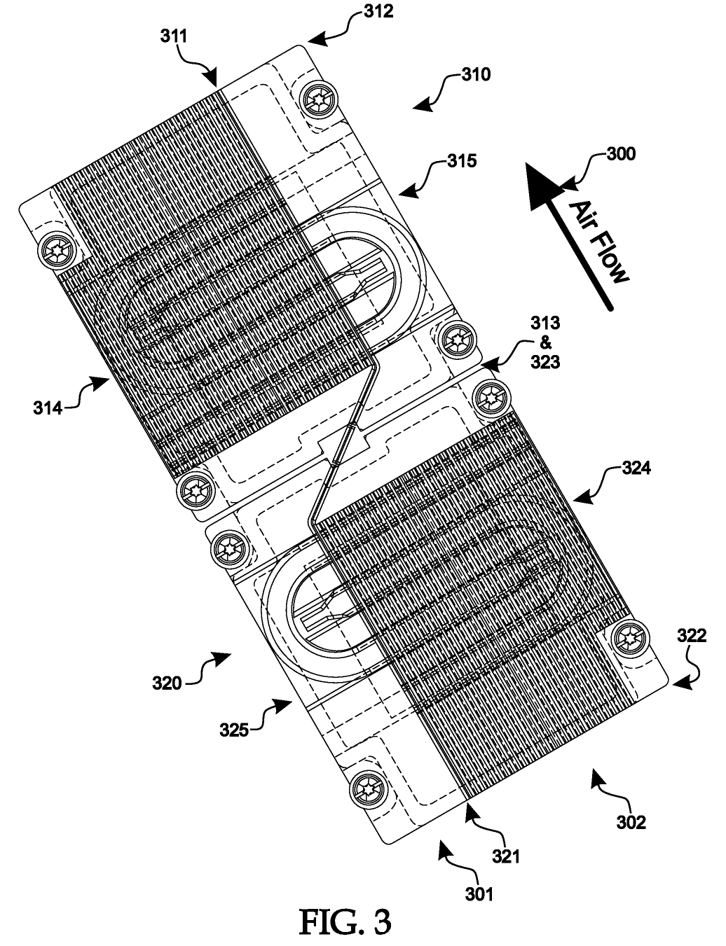

FIG. 3 is a top view of an exemplary embodiment of the invention. For discussion purposes, the direction of airflow is indicated by the arrow in the diagram (300) and is assumed to flow from front of the encompassing computer system toward the rear, as is standard in modern rack mounted computer systems. In a system with dual processors arranged in a back-to-back configuration, the processor heat sinks would be arranged with one rotated 180° with respect to the other, as illustrated by the identical heat sinks (310, 320) in the diagram resulting in an outer edge (312, 322) and in interior edge (313, 323). The two heat sinks (310, 320) comprise dividers (311, 321) which divide the cooling space into two cooling channels (301, 302). These dividers (311, 321) extend from the outer edge of the heat sinks (312, 322) to the interior edge (313, 323). The heat sinks each have cooling fins on only one side of the divider (314, 324) leaving the other side as an open air channel (315, 325). As these two sides are not of equal area, the dividers (311, 321) are angled near the interior edge (313, 323) such that they each bisect the center of the dividing plane between the heat sinks such that they meet to form a substantially complete air barrier between the two channels (301, 302). These dividers may be made from the same material as the cooling fins, and may also function as a cooling fin

In one embodiment, the meeting of the dividers may comprise an end-to-end alignment. In another embodiment, the meeting of the dividers may comprise an overlap of the ends of the divider. In another embodiment, the meeting of the dividers may comprise a physical connection bridging a gap between or joining the dividers.

In one embodiment the cooling fin may be made of an insulating material or may be adjoined to an insulating material to further reduce the pre-heating of the air flow in the clear air channel. In one embodiment, the top surface of the heat sink may be insulated from the clear air channel to further reduce the pre-heating of the air flow in the clear air channel.

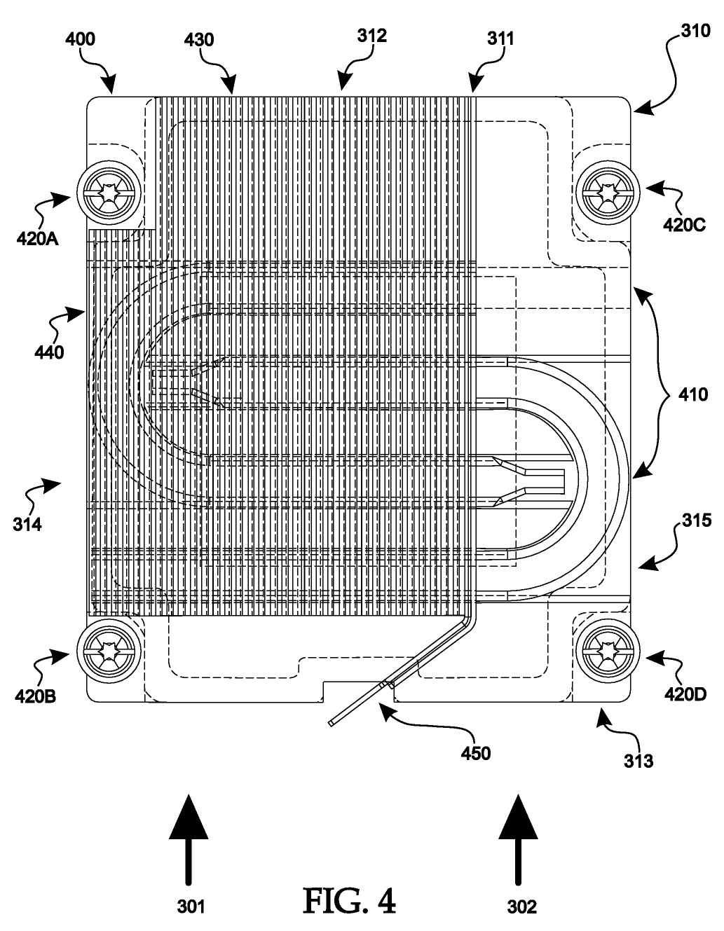

FIG. 4 is a top view of an exemplary embodiment of the invention. The flow diversion heat sink (310) comprises a divider (311) which extends from the outer edge (312) of the heat sink to the interior edge (313) of the heat sink. The heat sink has cooling fins (430, 440) on only one side of the divider (314) leaving the other side as an open air channel (315). This is to compensate for the increased wind resistance presented by the cooling fins (430, 440). As these two sides are not of equal area, the divider (311) is angled near the interior edge (313) such that it bisects the center of the interior edge (313) allowing it to align with an adjacent heat sink to form a substantially complete air barrier between the two channels (301, 302). The heat sink base (400) is secured to the circuit board or processor by fasteners (420A-D). In another embodiment, the heat sink may be fastened to the component. In other embodiments, the fastening may be accomplished by clips, clamps, or adhesives Heat pipes (410) are incorporated into the heat sink to ensure proper distribution of heat throughout the heat sink base.

Cooling fin efficiently at transferring heat from the processor to the air is relative to the fin's surface area. For this reason, cooling fin surfaces should be maximized. In the preferred embodiment of the invention, fasteners (420, and in particular 420A) may diminish the area available for cooling fin placement resulting in some cooling fins (440) being shorter in length than others (430). To compensate for the reduced length, shorter cooling fins (440) have a tighter spacing resulting in more fins in the same area, i.e. more surface area. Further, the reduced spacing under the same air pressure as the rest of the air channel experiences an increase in the speed of the air resulting in similar cooling capacity as the other cooling fins (430). Using the tighter spacing for all of the cooling fins would not be an ideal situation as it would increase the pressure necessary to force air through the system and this would negatively affect the fans and other system components.

In one embodiment of the invention, the divider may extend beyond the edges of the heat sink to ensure a tighter seal with adjacent components. In one embodiment, the divider may be made up of the same material, and itself perform the same function as a cooling fin in addition to functioning as a divider between the air channels. In another embodiment, the divider may be made of an insulating material to further reduce preheating of air passing through the open air channel. In another embodiment, the top of the heat sink base may be covered in an insulating material to reduce preheating of air passing through the open air channel. In another embodiment, the base contains a notch (450) to allow the divider to protrude below the base further ensuring an air seal.

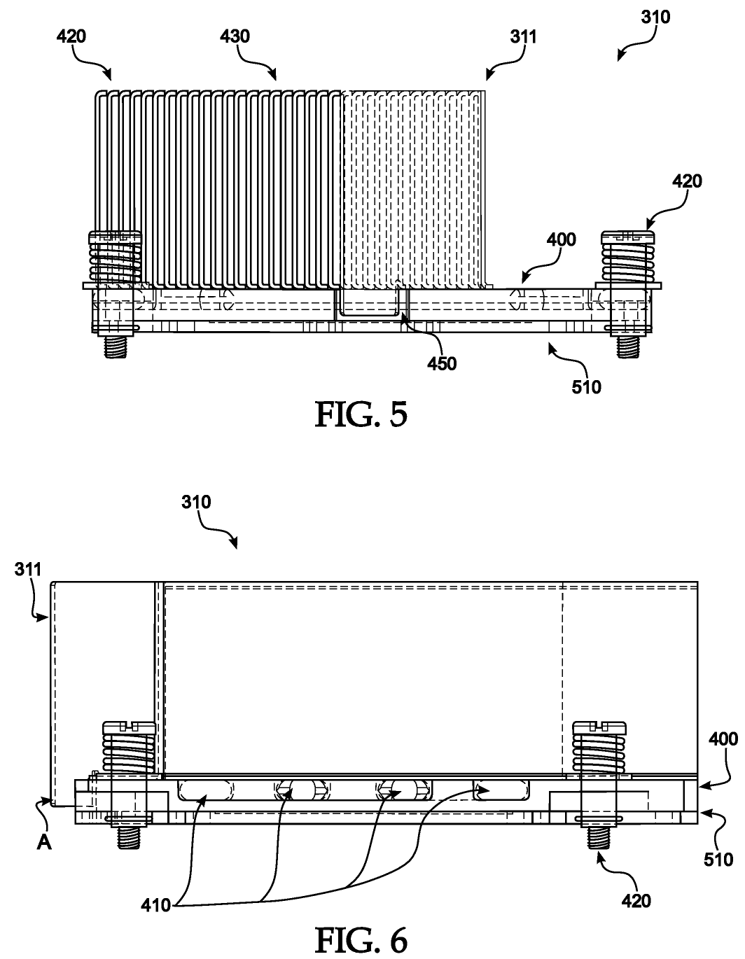

FIG. 5 and 6 are side views of an exemplary embodiment of the invention. FIG. 5 shows a flow diversion heat sink (310) from the interior edge (313 in previous figures). FIG. 6 shows a flow diversion heat sink (310) from the open air channel side (315 in previous figures). In these figures, the divider (311) can clearly be seen to extend beyond the base (400) of the heat sink at point A. The heat pipes (410) are shown embedded in the base (400) of the heat sink. In other embodiments, the heat pipes (410) may rest on top of the heat sink base (400) or may be omitted if the base material provides sufficient conductivity to adequately disperse heat uniformly. Also,, a gasket (510) is attached to the bottom of the heat sink base (400) to create a good seal between the bottom of the heat sink and the processor or circuit board to prevent air from bypassing the cooling fins.

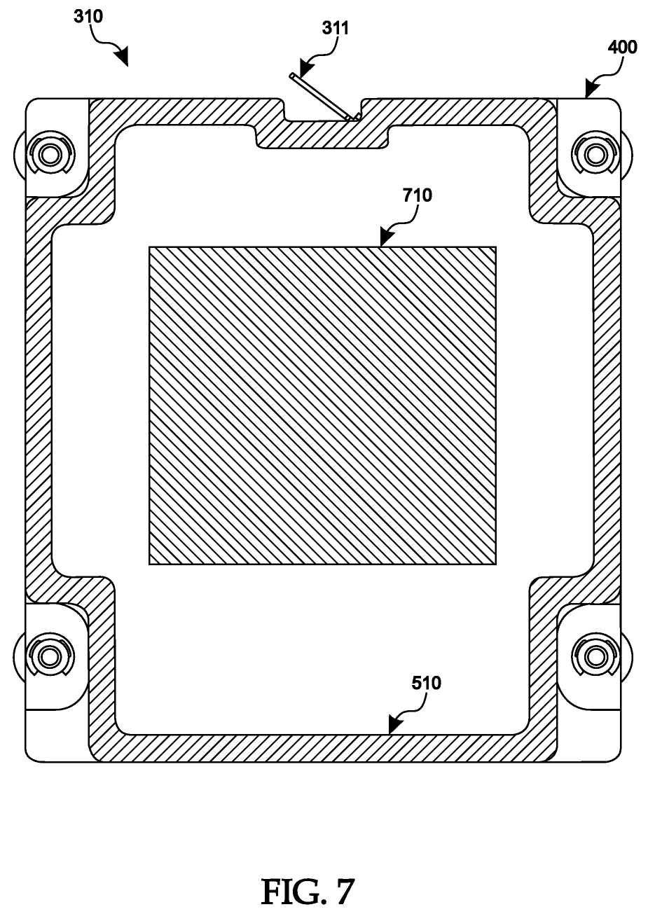

FIG. 7 is a bottom view of an exemplary embodiment of the invention. The gasket (510) extends around the approximately around the /perimeter of the heat sink base (400). The edge of the divider (311) is shown in this embodiment to extend past the edge of the heat sink base (400) so that it may overlap with the adjacent heat sink forming a barrier between the air channels. As is common practice in the industry, a heat-conducting compound (710) is used on the bottom of the heat sink to ensure proper conduction of heat between the protected component and the heat sink.

Specific numerical data values (such as specific quantities, numbers, categories, etc.) or other specific information should be interpreted as illustrative for discussing exemplary embodiments. Such specific information is not provided to limit the invention.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A system for maintaining heat sink temperature uniformity comprising;
a pair of substantially similar components mounted on a surface in close proximity, and substantially aligned with an air flow;
a pair of heat sinks each comprising:
a base;
a divider extending from one approximate edge of the base to the opposite approximate edge of the base, and radiating upward from the base;
a plurality of cooling fins on one side of the divider; and
and a clear air channel on the other side of the divider;
the heat sinks attached to the components in a rotated fashion such that clear air channel of one heat sink aligns with the cooling fins of the other heat sink.

2. A system as in claim 1 wherein the heat sinks are adjoined.

3. A system as in claim 1 wherein each heat sink further comprises a gasket around the bottom perimeter of the heat sink base preventing airflow between the heat sink base and the surface of the circuit board.

4. A system as in claim 1 wherein the heat sinks further comprise one or more fasteners for fastening to the circuit board.

5. A system as in claim 1 wherein the heat sinks further comprise one or more fasteners for fastening to the component.

6. A system as in claim 1 wherein the heat sinks are substantially similar shape.

7. A system as in claim 1 further comprising a plurality of pairs of heat sinks.

8. An apparatus for dissipating heat from a component comprising:
a base,
a divider extending across the top of the base from one side to the opposite side,
a plurality of cooling fins on one side of the divider radiating upward from the top side of the base and running parallel to the divider, and
a clear air channel on the other side of the divider.

9. An apparatus as in claim 8 wherein the clear air channel comprises less than half the area of the base's top surface.

10. An apparatus as in claim 8 wherein the divider extends at least to one edge of the heat sink base.

11. An apparatus as in claim 8 wherein the divider comprises an inclined plane extending from one end of the divider to substantially the middle of one edge of the heat sink base.

12. An apparatus as in claim 8 wherein the divider extends below the top edge of the heat sink base.

13. An apparatus as in claim 12 wherein the heat sink base comprises a notched portion to accommodate the portion of the divider extending below the top edge of the heat sink base.

14. An apparatus as in claim 8 wherein the divider of a heat sink comprises a cooling fin.

15. An apparatus as in claim 8 wherein the divider of a heat sink comprises an insulator for insulating the cooling fins from the clear air channel.

16. An apparatus as in claim 15 wherein the heat sink further comprises an insulator for insulating the heat sink base from the clear air channel.

17. An apparatus as in claim 8 wherein the heat sink base comprises a means for substantially uniformly distributing heat between the clear air channel side of the base and the cooling fin side of the base.

18. An apparatus as in claim 8 wherein the heat sink base comprises heat pipes.

19. An apparatus as in claim 8 wherein the heat sink further comprises fasteners for fastening to a circuit board.

20. An apparatus as in claim 8 wherein the heat sink further comprises fasteners for fastening to a component.

21. An apparatus as in claim 8 wherein the heat sink further comprises a gasket adjoining the bottom side of the heat sink base to a surface on which the heat sink is fastened.

22. An apparatus as in claim 8 wherein the spacing of the plurality of cooling fins is non-linear.

23. An apparatus as in claim 8 wherein the length of the plurality of cooling fins is not uniform.

24. A method of maintaining heat sink temperature uniformity comprising;
dividing an air flow across a plurality of heat sinks into a plurality of air flows;
directing one of the air flows past at least one of the heat sinks without substantially pre-heating, and further directing that air flow through the plurality of cooling fins of another of the plurality of heat sinks.
